(19) United States
(12) Patent Application Publication
(10) Pub. No.: US 2025/0247022 A1
(43) Pub. Date: Jul. 31, 2025

(54) UTILIZING PIEZOELECTRIC GENERATION TO HARNESS WASTE ENERGY IN FLOW LIMITERS USED IN REMOTE WELL SITE

(71) Applicant: SAUDI ARABIAN OIL COMPANY, Dhahran (SA)

(72) Inventors: Rashed A. Altowairqi, Taif (SA); Khalaf A. Alotaibi, Abqaiq (SA); Akram R. Barghouti, Khobar (SA); Mohammed H. Madan, Al Qatif (SA)

(73) Assignee: SAUDI ARABIAN OIL COMPANY, Dhahran (SA)

(21) Appl. No.: 18/423,095

(22) Filed: Jan. 25, 2024

(51) Int. Cl. H02N 2/18; H10N 30/88

(52) U.S. Cl. CPC H02N 2/185; H02N 2/181; H02N 2/186; H10N 30/88

(57) ABSTRACT

Systems and methods for converting vibrations to electrical energy, including a mechanical device producing vibrations during operation, a flexible piezoelectric sheet, and a junction box. The flexible piezoelectric sheet includes protective layers, piezoelectric element layers, electrode layers, and an adhesive layer to attach the flexible piezoelectric sheet to the mechanical device. The piezoelectric element layer converts vibrations into an electric charge and is provided between a first electrode layer and a second electrode layer which are physically separated from one another. The junction box includes an electrical circuit and battery and collects and stores generated electrical energy. Methods include converting vibrations from a mechanical device to electrical energy by disposing a flexible piezoelectric sheet on the mechanical device, electrically connecting the flexible piezoelectric sheet to a junction box, harvesting, and storing generated energy in the junction box, and providing stored energy to a device requiring power located at a wellsite.

### BACKGROUND

Many well sites are in a remote location with limited or no power supply. Having a source of power in remote locations is crucial for many purposes such as powering up and testing electrical devices for a job, charging cell phones, among countless other applications. One way to provide power to remote locations is by using piezoelectric materials. Piezoelectric materials generate an electric charge when subjected to mechanical strain or pressure, such as vibrations or motion. The piezoelectric effect results from a linear electromechanical interaction between crystalline materials with no inversion symmetry in their crystalline unit cell. Materials which exhibit piezoelectric properties are generally ceramic, polymer, or composite materials. Overall, piezoelectric materials are a versatile class of energy-generating materials which may be used in a wide range of applications.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a system for converting vibrations to electrical energy, including a mechanical device producing vibrations during operation or use, a flexible piezoelectric sheet, and a junction box. The flexible piezoelectric sheet includes at least one protective layer, at least one piezoelectric element layer, at least one electrode layer, each at least one electrode layer including an electrical connection point, and an adhesive layer configured to attach the flexible piezoelectric sheet to the mechanical device. The piezoelectric element layer is configured to convert the vibrations into an electric charge and is provided between a first electrode layer and a second electrode layer such that the first electrode layer is physically separated from the second electrode layer, and at least one protective layer is provided on an outer surface of the flexible piezoelectric sheet. The junction box includes an electrical circuit and battery, where the junction box is configured to collect and store generated electrical energy, and where the junction box is electrically connected by a first electrical connector to a first electrical connection point located on the first electrode layer of the flexible piezoelectric sheet and by a second electrical connector to a second electrical connection point located on the second electrode layer of the flexible piezoelectric sheet.

In another aspect, embodiments disclosed herein relate to a method for converting vibrations to electrical energy, including locating a mechanical device at a wellsite, wherein the mechanical device produces vibrations during operation, and disposing a flexible piezoelectric sheet on the mechanical device, where the flexible piezoelectric sheet includes at least one protective layer, at least one piezoelectric element layer, at least one electrode layer, each at least one electrode layer including an electrical connection point, and an adhesive layer configured to attach the flexible piezoelectric sheet to the mechanical device. The piezoelectric element layer is configured to convert the vibrations into an electric charge and is provided between a first electrode layer and a second electrode layer such that the first electrode layer is physically separated from the second electrode layer, and at least one protective layer is provided on an outer surface of the flexible piezoelectric sheet. The method also includes electrically connecting, to a junction box, a first electrical connection point located on the first electrode layer of the flexible piezoelectric sheet using a first electrical connector, where the junction box includes an electrical circuit and battery, and the junction box is configured to collect, and store generated electrical energy. The method also includes electrically connecting, to the junction box, a second electrical connection point located on the second electrode layer of the flexible piezoelectric sheet using a second electrical connector, harvesting the generated electrical energy, and storing the generated electrical energy in the junction box, and providing the stored electrical energy from the junction box to a device requiring power located at the wellsite.

Other aspects and advantages of the claimed subject matter will be apparent from the following description and the appended claims.

### BRIEF DESCRIPTION OF DRAWINGS

FIG. 1A is a system for converting vibrations to electrical energy in accordance with one or more embodiments.

FIG. 1B is an example system in accordance with one or more embodiments.

FIG. 2A shows a side view of a flexible piezoelectric sheet according to one or more embodiments.

FIG. 2B shows an internal view of a flexible piezoelectric sheet according to one or more embodiments.

FIG. 3 is a flowchart of a method according to one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (for example, first, second, third) may be used as an adjective for an element (that is, any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

It is to be understood that the singular forms “a,” “an,” and “the” include plural referents unless the context clearly dictates otherwise. Thus, for example, reference to “a fluid sample” includes reference to one or more of such samples.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope of the invention should not be considered limited to the specific arrangement of steps shown in the flowcharts.

Although multiply dependent claims are not introduced, it would be apparent to one of ordinary skill that the subject matter of the dependent claims of one or more embodiments may be combined with other dependent claims.

Piezoelectric materials may be used to convert energy that would otherwise go to waste into useful, electrical energy. During oilfield operations, countless devices produce mechanical energy, such as vibrations and motion, which generally goes to waste. One example is a flow limiter. Fluid flow through flow limiters undergoes pressure drop which results in vibration in the flow limiter's body. These vibrations are typically wasted mechanical energy that can be harnessed, for example, using piezoelectric materials. Piezoelectric materials may therefore be placed on or near a device, such as a flow limiter, to convert mechanical energy from vibrations into electrical energy. The generated electrical energy may then be stored and subsequently used, for example, in a remote well site area which may not have access to a power source otherwise.

Embodiments disclosed herein generally relate to systems and methods for converting vibrations to electrical energy. Systems and methods disclosed herein include a mechanical device which produces vibrations during operation, a flexible piezoelectric sheet, and a junction box. The mechanical device may be a flow limiter, or other mechanical device which vibrates during operation. The flexible piezoelectric sheet converts said vibrations into electrical energy. The junction box collects and stores the generated electrical energy for later use.

### System for Converting Vibrations to Electrical Energy

Embodiments disclosed herein relate to a system for converting vibrations to electrical energy. The system of one or more embodiments includes a mechanical device which produces vibrations, a flexible piezoelectric sheet, and a junction box.

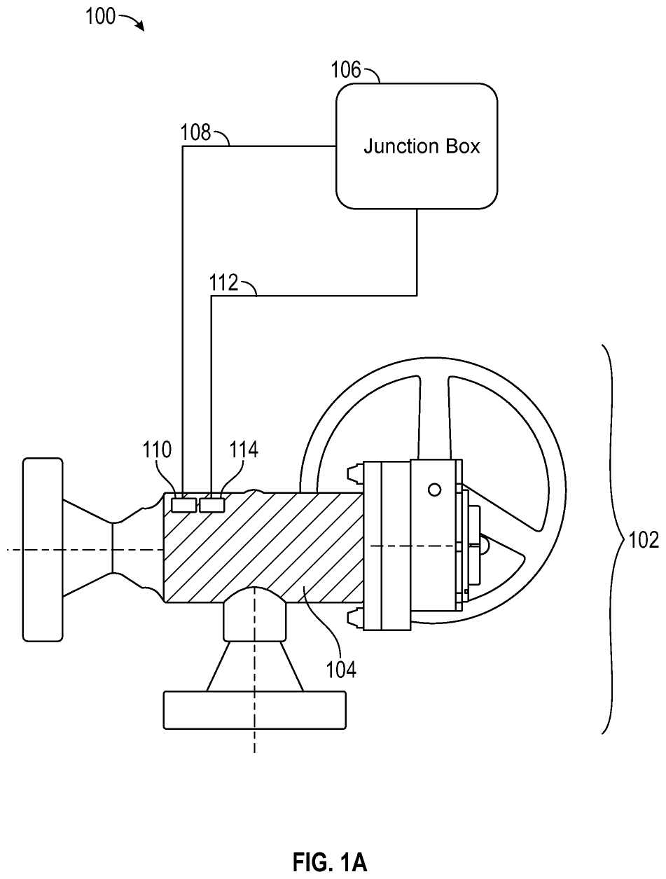

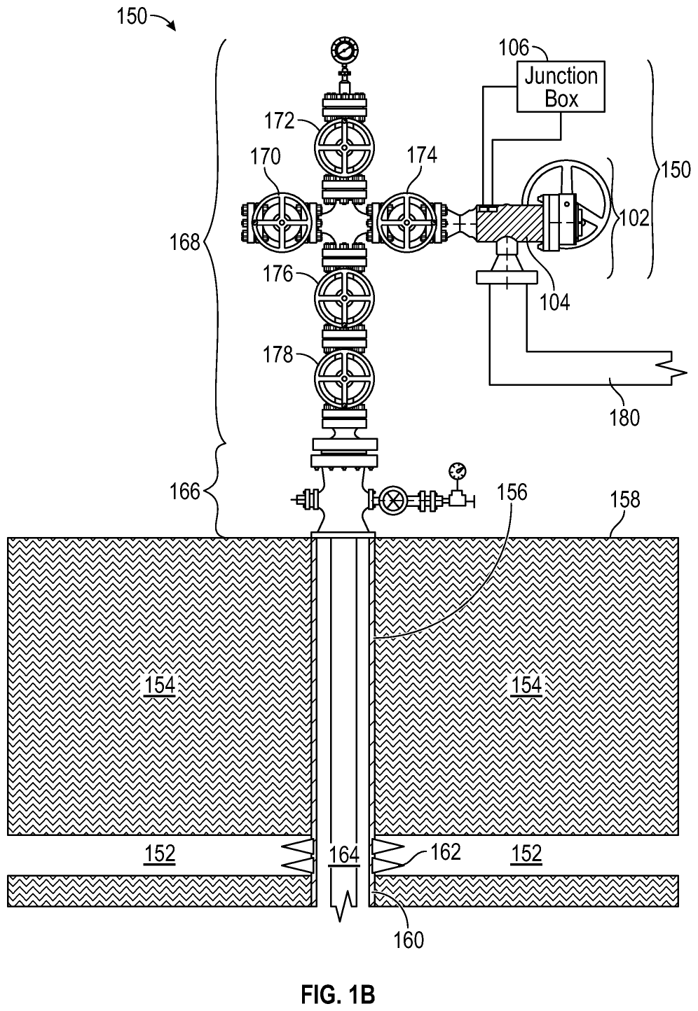

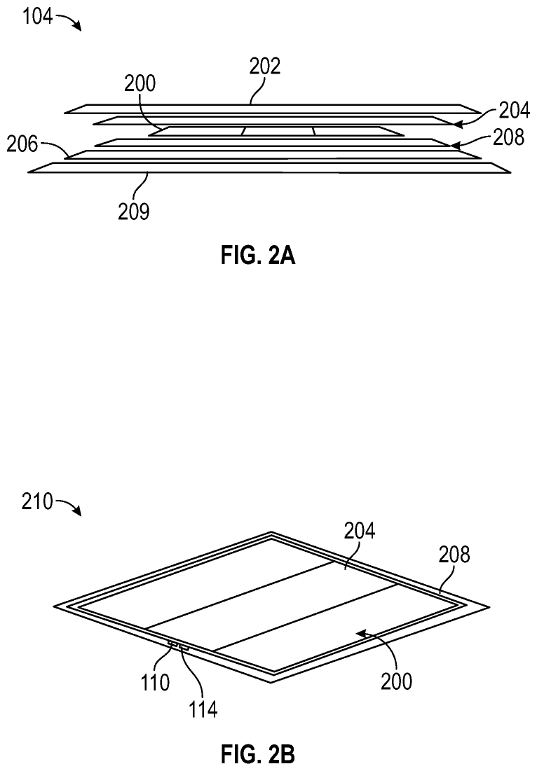

FIG. 1A shows a system 100 for converting vibrations to electrical energy according to one or more embodiments. In FIG. 1A, a mechanical device 102 produces mechanical vibrations during normal operation and use of the mechanical device 102. Generally, mechanical energy produced from said mechanical vibrations would be lost to the environment and therefore wasted. Instead, piezoelectric devices may be used to harness the mechanical energy from mechanical vibrations and produce electrical energy, for example, using embodiments disclosed herein. In the system 100 of FIG. 1A, a flexible piezoelectric sheet 104 is attached to the mechanical device 102 which creates mechanical vibrations. In one or more embodiments, the flexible piezoelectric sheet includes an adhesive layer, where the adhesive layer is configured to attach the flexible piezoelectric sheet to the mechanical device 102. The details of the flexible piezoelectric sheet will be described more in relation to FIGS. 2A-2C.

The mechanical device of one or more embodiments is any component which produces mechanical vibration during operation and use. In one or more embodiments, the mechanical device is any component which produces mechanical vibration due to a pressure drop from a fluid flowing through the mechanical device. For example, the mechanical device may be a flow limiter device, such as a choke valve or any other device attached to the wellhead, for example, any one or more valve as part of the Christmas tree 168 (shown in FIG. 1B), configured to control the fluids being injected into or pumped out of the wellbore 156 (shown in FIG. 1B).

Keeping with FIG. 1A, the system 100 for converting vibrations to electrical energy of one or more embodiments also includes a junction box 106. The junction box 106 includes an electrical circuit and battery and is configured to collect and store electrical energy generated by the flexible piezoelectric sheet 104. The flexible piezoelectric sheet 104 includes a first electrical connection point 110 electrically connected by a first electrical connector 108 to the junction box 106. Similarly, the flexible piezoelectric sheet 104 includes a second electrical connection point 114 electrically connected by a second electrical connector 112 to the junction box 106.

The junction box 106 according to one or more embodiments is any device used to store electrical energy generated by the flexible piezoelectric sheet 104. The junction box may be a device dedicated to the system 100 for converting vibrations to electrical energy or the junction box may be part of a larger electrical system. The junction box may include an electric circuit or circuits. The junction box may include a battery to store electrical energy and electrical outlet, or outlets connected to the battery in order to discharge the stored electrical energy to an external device.

The first electrical connector 108 and the second electrical connector 112 of one or more embodiments are any electrical connectors capable of transmitting electrical energy generated by the flexible piezoelectric sheet 104 to the junction box 106. For example, the first electrical connector and the second electrical connector may be a metal wire or cable, such as copper, gold, silver, aluminum, tungsten, and the like.

The first electrical connection point 110 and the second electrical connection point 114 of one or more embodiments are any electrical connection point capable of providing an electrical connection between the flexible piezoelectric sheet 104 and an electrical connector. For example, the first electrical connection point and the second electrical connection point may be a flexible metal electrode, such as silver or nickel, or the like. The electrical connection points may be connected to the flexible piezoelectric sheet by soldering or other known connection methods.

An example system for converting vibrations to electrical energy is presented in FIG. 1B. The system 150 of FIG. 1B illustrates an example well site including the system 100 for converting vibrations to electrical energy of one or more embodiments.

In the oil and gas industry, as illustrated by the system 150 of FIG. 1B, fluids are produced from a reservoir 152 in a formation 154 by drilling a wellbore 156 into the formation 154, establishing a flow path between the reservoir 152 and the wellbore 156, and conveying the fluids from the reservoir 152 to a surface 158 through the wellbore 156. A casing 160 may be installed in wellbore 156. In some embodiments, the casing 160 may be perforated to have perforations 162 into the reservoir 152 to allow a flow of the fluids to enter the wellbore 156. Typically, a production tubing 164 is disposed in the wellbore 156 to carry the fluids to the surface 158. The production tubing 164 hangs from a wellhead 166 at the surface 158. The production tubing 164 extends past the reservoir 152, thereby forming a flow conduit from the reservoir 152 to surface 158.

A tree (also known as a Christmas tree) 168 is disposed on top of the wellhead 166 to control the flow of fluids into or out of the wellbore 156, depending on whether it is an injection well or a production well. Christmas tree 168 includes a configuration of valves to control the fluids being injected into or pumped out of the wellbore 156. For example, the Christmas tree 168 may have an injection wing valve 170, a swab valve 172, a production wing valve 174, an upper master valve 176, and a lower master valve 178. When an operator is ready to conduct well operations the valves 170-178 are either opened or closed to control the fluids being injected into or pumped out of the wellbore 156. During injection, the production wing valve 174 and the swab valve 172 are closed while the injection wing valve 170, the upper master valve 176, and the lower master valve 178 are open to allow for fluids to be injected through the Christmas tree 168 and into the wellbore 156. During production, the injection wing valve 170 and the swab valve 172 are closed while the production wing valve 174, the upper master valve 176, and the lower master valve 178 are open to control or isolate fluid flow through a choke valve 102. From the choke valve 102, the fluids are transported via a production flow line 180, to a production storage, transport, or facility.

The choke valve 102 is a mechanical device to control flow rates and pressure drops of the produced fluids. For example, an operational function of the choke valve 102 is to produce the fluids from the wellbore 156 at the desired rates by the introduction of human intervention to manually control the drawdown pressure.

During wellbore operations such as injection, intervention, fracking, etc. or as fluids are produced from the wellbore 156, one or more of the valves shown in FIG. 1B may vibrate due to fluid flowing through the valves. Therefore, the valves shown in FIG. 1B may be suitable candidates for energy collection according to embodiments disclosed herein.

Keeping with FIG. 1B, a system 150 for converting vibrations to electrical energy according to one or more embodiments may also be coupled to a fluid production system in the oil and gas industry, as described above. The system 150 may include a choke valve 102, which may be fluidly connected to a downstream side of the production wing valve 174 and to an upstream side of the production flow line 180. As described above, the choke valve 102 controls produced fluids which experience a pressure drop as the produced fluids flow across the choke. This pressure drop may produce a mechanical vibration which may be transmitted to a flexible piezoelectric sheet, where the flexible piezoelectric sheet envelops the choke valve 102, as will be described in more detail in the following figures.

As one of ordinary skill in the art will appreciate, there are numerous components and devices used in oil and gas operations which undergo vibrations and may therefore be used with the energy harvesting system as described in one or more embodiments. The system of FIG. 1B is merely an example of one type of oil and gas system which may benefit from the system 150 for converting vibrations to electrical energy disclosed herein and is not intended to be limiting.

FIGS. 2A-2C show a flexible piezoelectric sheet 104 in accordance with one or more embodiments. FIG. 2A shows a side view of the flexible piezoelectric sheet 104. The flexible piezoelectric sheet 104 of one or more embodiments includes a layered structure. The layers include, but are not limited to, protective layers, piezoelectric element layers, and electrode layers. In the example flexible piezoelectric sheet 104 of FIG. 2A, a first protective layer 202 is located on a first side of the flexible piezoelectric sheet 104, where the first side represents an outer surface of the flexible piezoelectric sheet 104.

A first electrode layer 204 may be connected to the first protective layer 202 on one side of the first electrode layer 204. On an opposite side of the first electrode layer 204 may be a piezoelectric element layer 200, followed by a second electrode layer 208 located on a side of the piezoelectric element layer 200 which is connected opposite of the side contacting the first electrode layer 204. In one or more embodiments, the flexible piezoelectric sheet 104 functions as a mechanical structure configured to convert vibrations into a mechanical stress and generate an electric charge having a magnitude in proportion to the mechanical stress.

A second protective layer 206 may be connected to the second electrode layer 208 on an opposite side from the piezoelectric element layer 200. In one or more embodiments, an adhesive layer 209, located on an outer surface of the second protective layer 206, is configured to attach the flexible piezoelectric sheet to a mechanical device 102 which produces vibrations.

The protective layers according to one or more embodiments are constructed from insulating materials. For example, the protective layers may be constructed from an insulating material, such a polymer. The polymer may be any suitable polymer capable of isolating and protecting the internal piezoelectric sheet from deterioration. For example, the polymer may be a polyethylene terephthalate, polypropylene, polyethylene, silicone, and combinations thereof.

The protective layers of one or more embodiments have a suitable thickness which provides a balance between flexibility and structural integrity of the flexible piezoelectric sheet. As a non-limiting example, the protective layer may have a thickness in a range of about 1 mm to about 2 mm. For example, the protective layers may have a thickness in a range having a lower limit of from about 1 mm, 1.25 mm, and 1.5 mm to an upper limit of about 1.75 mm, and 2 mm, where any lower limit may be paired with any upper limit.

The piezoelectric element layers according to one or more embodiments may be any flexible piezoelectric material known in the art. The piezoelectric element layer may be constructed from a Rochelle salt, a polymer composite, a polymer nanocomposite, piezoelectric ceramic materials, piezoelectric crystal materials, semiconductors, and the like.

The piezoelectric element layer of one or more embodiments has a total thickness of less than 1 mm. For example, the piezoelectric element layer may have a total thickness of 1 mm, 0.75 mm, 0.5 mm, 0.25 mm, or 0.1 mm.

In one or more embodiments, the flexible piezoelectric sheet includes more than one piezoelectric element layer. Inclusion of more than one piezoelectric element layers may improve the efficiency of the flexible piezoelectric sheet to convert vibrations into a mechanical stress and electric charge according to one or more embodiments.

The electrode layers according to one or more embodiments are constructed from conductive materials. For example, the electrode layers may be constructed from a metal, such as copper, gold, silver, aluminum, tungsten, and the like.

The electrode layers of one or more embodiments have a thickness in a range of about 1 mm to about 2 mm. For example, the electrode layers may have a thickness in a range having a lower limit of from about 1 mm, 1.25 mm, and 1.5 mm to an upper limit of about 1.75 mm, and 2 mm, where any lower limit may be paired with any upper limit.

The adhesive layer according to one or more embodiments may be any suitable adhesive material known in the art capable of adhering the flexible piezoelectric sheet to the mechanical device which produces vibrations.

The flexible piezoelectric sheet 104 of one or more embodiments has a total thickness of less than 5 mm. For example, the flexible piezoelectric sheet may have a total thickness of 5 mm, 4 mm, 3 mm, 2 mm, or 1 mm.

The flexible piezoelectric sheet 104 is a flexible device, designed to fit around or attach to a mechanical device without interfering with the function of the mechanical device.

While FIG. 2A shows one example of a layered structure for the flexible piezoelectric sheet 104 or one or more embodiments, the flexible piezoelectric sheet 104 is not limited to this specific structure and layer configuration. The flexible piezoelectric sheet may include one or more protective layers, located at an outer surface of the flexible piezoelectric sheet or at an inner surface of the flexible piezoelectric sheet. The flexible piezoelectric sheet includes at least two electrode layers, where each of the electrode layers do not contact one another. However, any number of electrode layers may be included in the flexible piezoelectric sheet. The flexible piezoelectric sheet may also include any number of piezoelectric element layers.

FIG. 2B shows an interior view 210 of the flexible piezoelectric sheet 104 of one or more embodiments. The first electrode layer 204 may be connected to a piezoelectric element layer 200, followed by the second electrode layer 208 located on a side of the piezoelectric element layer 200 which is connected opposite of the side contacting the first electrode layer 204. The first electrical connection point 110 may be a flexible electrode located on the first electrode layer 204. The second electrical connection point 114 may be a flexible electrode located on the second electrode layer 208. In one or more embodiments, a wire or other electrical connector 108, 112 may protrude from the interior of the flexible piezoelectric sheet and may be connected to the first and second electrical connection point 110, 114, respectively, as described in FIG. 1A.

### Method for Converting Vibrations to Electrical Energy

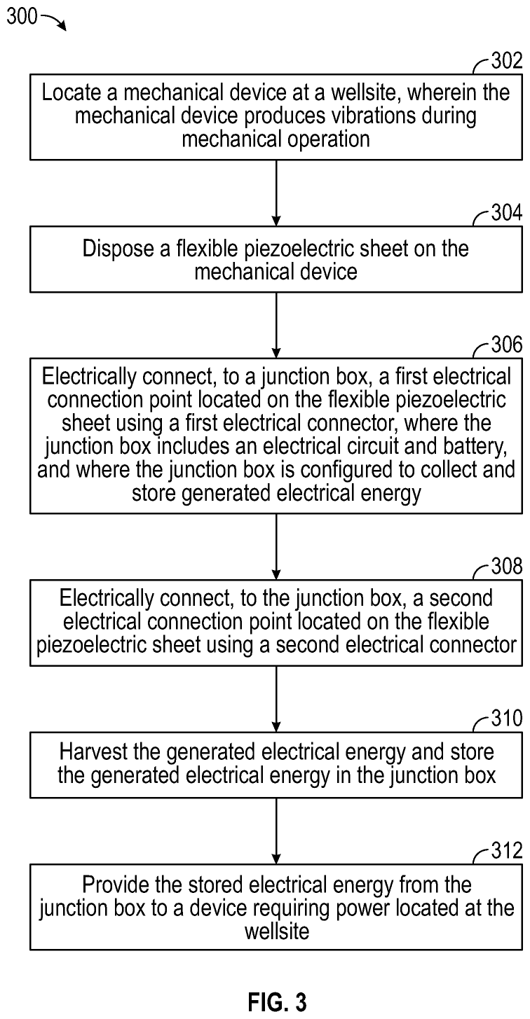

Embodiments disclosed herein also relate to a method for converting vibrations to electrical energy. The method 300 of one or more embodiments is described in the flowchart of FIG. 3. In one or more embodiments the method 300 includes, in step 302, locating a mechanical device at a wellsite, wherein the mechanical device produces vibrations during operation and use. In some embodiments, the mechanical device is a flow limiter.

The method 300 of one or more embodiments also includes, in step 304, disposing a flexible piezoelectric sheet on the mechanical device, where the flexible piezoelectric sheet includes at least one protective layer, at least one piezoelectric element layer, at least one electrode layer, each electrode layer having an electrical connection point, an adhesive layer configured to attach the flexible piezoelectric sheet to the mechanical device, and a mechanical structure configured to introduce stress on the at least one piezoelectric element layer due to the vibrations, where the at least one piezoelectric element layer is provided between a first electrode layer and a second electrode layer such that the first electrode layer is physically separated from the second electrode layer, and where at least one protective layer is provided on an outer surface of the flexible piezoelectric sheet.

In some embodiments, the flexible piezoelectric sheet has a total thickness of less than 5 mm. In some embodiments, the piezoelectric element layer has a thickness of less than 1 mm. In some embodiments the at least one electrode layer has a thickness of from 1 mm to 2 mm. In some embodiments, the piezoelectric element layer includes a Rochelle salt, a polymer composite, a polymer nanocomposite, a piezoelectric ceramic material, a piezoelectric crystal material, or a semiconductor. In some embodiments, the flexible piezoelectric sheet includes more than one piezoelectric element layer. In some embodiments, the at least one electrode layer includes a conductive metal.

In one or more embodiments the method 300 includes, in step 306, electrically connecting, to a junction box, a first electrical connection point located on the first electrode layer of the flexible piezoelectric sheet using a first electrical connector, where the junction box includes an electrical circuit and battery, and where the junction box is configured to collect and store generated electrical energy.

In one or more embodiments the method 300 includes, in step 308, electrically connecting, to the junction box, a second electrical connection point located on the second electrode layer of the flexible piezoelectric sheet using a second electrical connector.

In one or more embodiments the method 300 includes, in step 310, harvesting the generated electrical energy and storing the generated electrical energy in the junction box.

In one or more embodiments the method 300 includes, in step 312, providing the stored electrical energy from the junction box to a device requiring power located at the wellsite.

In one or more embodiments, the amount of energy generated may depend upon the size of the piezoelectric sheet, the number of piezoelectric element layers and/or cells contained within the sheet, the magnitude of vibrations, the efficiency of conversion of vibrations to mechanical stress and further to electricity, and other variables.

In one or more embodiments, a plurality of mechanical devices are outfitted with flexible piezoelectric sheets according to one or more embodiments. Flexible piezoelectric sheets disposed on the plurality of mechanical devices may then be connected to a common junction box such that electricity generated from multiple sources may be collected and stored in one location.

### Advantages of Embodiments Disclosed Herein May Include the Following.

Systems and methods for converting vibrations to electrical energy of one or more embodiments are non-intrusive and may harness and store electrical energy without interfering with normal operations of the device(s) upon which they are installed. Installation of the flexible piezoelectric sheet involves attaching the sheet to a mechanical device's walls with adhesive material and connecting it to an external junction box. The junction box then serves as a versatile energy source for multiple purposes.

Systems and methods for converting vibrations to electrical energy of one or more embodiments provide a positive environmental impact, as energy losses due to pressure drop across flow limiter devices will be utilized as an energy source. In addition, no external mechanical energy is required to produce electrical energy, only vibrations from the covered device.

Systems and methods for converting vibrations to electrical energy of one or more embodiments can be used for remote areas where finding an energy source is a challenge. Where, for example, generated energy may be utilized to power an energy outlet in remote well sites.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A system for converting vibrations to electrical energy, comprising:
a mechanical device, wherein the mechanical device produces vibrations during operation or use;
a flexible piezoelectric sheet, wherein the flexible piezoelectric sheet comprises;
at least one protective layer,
a piezoelectric element layer,
at least one electrode layer, each at least one electrode layer comprising an electrical connection point, and
an adhesive layer configured to attach the flexible piezoelectric sheet to the mechanical device,
wherein the piezoelectric element layer is configured to convert the vibrations into an electric charge,
wherein the piezoelectric element layer is provided between a first electrode layer and a second electrode layer such that the first electrode layer is physically separated from the second electrode layer, and
wherein the at least one protective layer is provided on an outer surface of the flexible piezoelectric sheet; and
a junction box comprising an electrical circuit and battery, wherein the junction box is configured to collect and store generated electrical energy,
wherein the junction box is electrically connected by a first electrical connector to a first electrical connection point located on the first electrode layer of the flexible piezoelectric sheet and by a second electrical connector to a second electrical connection point located on the second electrode layer of the flexible piezoelectric sheet.

2. The system of claim 1, wherein the mechanical device comprises a flow limiter located at a well site.

3. The system of claim 1, wherein the flexible piezoelectric sheet has a total thickness of less than 5 mm.

4. The system of claim 1, wherein the piezoelectric element layer has a thickness of less than 1 mm.

5. The system of claim 1, wherein the piezoelectric element layer comprises a Rochelle salt, a polymer composite, a polymer nanocomposite, a piezoelectric ceramic material, a piezoelectric crystal material, or a semiconductor.

6. The system of claim 1, wherein the flexible piezoelectric sheet comprises more than one piezoelectric element layer.

7. The system of claim 1, wherein the at least one electrode layer comprises a conductive metal.

8. The system of claim 1, wherein each of the at least one electrode layers has a thickness of from 1 mm to 2 mm.

9. A method for converting vibrations to electrical energy, comprising:
locating a mechanical device at a wellsite, wherein the mechanical device produces vibrations during operation;
disposing a flexible piezoelectric sheet on the mechanical device, wherein the flexible piezoelectric sheet comprises;
at least one protective layer,
a piezoelectric element layer,
at least one electrode layer, each at least one electrode layer comprising an electrical connection point, and
an adhesive layer configured to attach the flexible piezoelectric sheet to the mechanical device,
wherein the piezoelectric element layer is configured to convert the vibrations into an electric charge,
wherein the piezoelectric element layer is provided between a first electrode layer and a second electrode layer such that the first electrode layer is physically separated from the second electrode layer, and
wherein the at least one protective layer is provided on an outer surface of the flexible piezoelectric sheet;
electrically connecting, to a junction box, a first electrical connection point located on the first electrode layer of the flexible piezoelectric sheet using a first electrical connector,
wherein the junction box comprises an electrical circuit and battery, and wherein the junction box is configured to collect and store generated electrical energy;
electrically connecting, to the junction box, a second electrical connection point located on the second electrode layer of the flexible piezoelectric sheet using a second electrical connector;
harvesting the generated electrical energy and storing the generated electrical energy in the junction box; and
providing the stored electrical energy from the junction box to a device requiring power located at the wellsite.

10. The method of claim 9, wherein the mechanical device is a flow limiter.

11. The method of claim 9, wherein the flexible piezoelectric sheet has a total thickness of less than 5 mm.

12. The method of claim 9, wherein the piezoelectric element layer has a thickness of less than 1 mm.

13. The method of claim 9, wherein the piezoelectric element layer comprises a Rochelle salt, a polymer composite, a polymer nanocomposite, a piezoelectric ceramic material, a piezoelectric crystal material, or a semiconductor.

14. The method of claim 9, wherein the flexible piezoelectric sheet comprises more than one piezoelectric element layer.

15. The method of claim 9, wherein the at least one electrode layer comprises a conductive metal.

16. The method of claim 9, wherein each of the at least one electrode layers has a thickness of from 1 mm to 2 mm.
